(19) United States
(12) Patent Application Publication
(10) Pub. No.: US 2007/0022956 A1
(43) Pub. Date: Feb. 1, 2007

(54) Evaporator device

(76) Inventors: Marcus Bender, Hanau (DE); Uwe Hoffmann, Alzenau (DE); Gunter Klemm, Nidda (DE); Dieter Haas, Bruchkobel (DE); Ulrich Englert, Heigenbrucken (DE)

Correspondence Address: FULBRIGHT & JAWORSKI, LLP, 666 FIFTH AVE, NEW YORK, NY, 10103-3198, US

(21) Appl. No.: 11/384,174

(22) Filed: Mar. 17, 2006

(30) Foreign Application Priority Data
Jul. 28, 2005 (EP) 050 16 364

(51) Int. Cl. C23C 16/00

(52) U.S. Cl. 118/726

(57) ABSTRACT

An evaporator device for coating substrates, in particular for applying an aluminum layer of OLEDs. To attain high evaporator tube temperatures, such as are required for example for the vaporization of materials with low vapor pressure, the heating system is placed into the interior of the evaporator tube. The thermal losses are thereby minimized and higher tube temperatures are possible at comparably coupled-in heating power.

### BACKGROUND AND SUMMARY OF THE INVENTION

This application claims priority under 35 U.S.C. §119 from European Patent Application No. 050 16 364 filed Jul. 28, 2005, incorporated herein by reference in its entirety.

The invention relates to an evaporator device.

Modern flat-screen displays comprise liquid crystal elements (LCDs) or plasma elements for the rendering of images or characters.

Flat-screen displays have also recently been produced which utilize organic light-emitting diodes (OLEDs) as color pixels.

Compared to the known structural elements, a great advantage of the OLEDs is their high degree of efficiency of more than 16% (Helmuth Lemme: OLEDs—Senkrechtstarter aus Kunststoff, Elektronik February 2000, p. 98, right column, 2nd paragraph, No. [5]: Yi He; Janicky, J.: High Efficiency Organic Polymer Light-Emitting Heterostructure Devices, Eurodisplay 99, VDE-Verlag Berlin, Offenbach). Therewith the OLEDs are situated far above the quantum efficiency of the LEDs comprised of inorganic III-V semiconductors.

OLEDs, further, have low weight, a wide angle of radiation, and produce colors of more intense brightness and can be applied in a broad temperature range from −40° C. to 85° C. Of advantage is also that they can be operated at less than 5 Volts and have low electric energy consumption, which makes the OLEDs especially suitable for installation in battery-operated apparatus.

The OLEDs can be produced by means of OVPD technology (OVPD=Organic Vapor Phase Deposition), such as is described in U.S. Pat. No. 5,554,220 or DE 101 28 091 C1. Therein the organic materials are applied onto an electrode located on glass. This electrode can be, for example, an ITO electrode (ITO=Indium Tin Oxide) which had previously been vapor deposited onto glass.

Onto the OLED layer generated in this way further materials, in particular metals, which assume the function of control electrodes, can be applied. Since OLEDs are heat sensitive, precautions must be taken to prevent the heat effect onto the OLEDs from becoming too strong.

As a rule, the heating sets for the evaporation of metals are disposed around an evaporator tube (DE 38 17 513 C2, DE 101 28 091 C1). The heating sets are vertical heating rods or coil heaters (DE 102 56038 A1, U.S. Pat. No. 4,880,960). Of disadvantage in heating systems located outside of the evaporator tube are their high thermal losses. When coating OLEDs with metals, where for the evaporation of the metals temperatures of more than 1200° C. must be generated, such heating sets have a negative effect on the OLEDs due to their heat radiation.

Furthermore is known an evaporator device for coating substrates, which comprises an evaporator with a heating system (U.S. Pat. No. 5,157,240 A). However, this evaporator device does not have a linear distributor opening.

From EP 0 581 496 A an evaporator device is also known, which serves for coating substrates. However, a linear distributor opening also does not exist here.

U.S. Pat. No. 6,117,498 A discloses a coating device with a vacuum chamber. In the center of this chamber is located an electric resistance heater in the form of a tantalum sheet. A linear distributor opening is not provided in this coating device.

In addition, a metal evaporator device is known with a cylindrical tube as the evaporator. This tube comprises a rod-shaped resistance heater (DE 41 33 615 A). This device also does not include a linear distributor opening.

The invention addresses the problem of providing an evaporator device in which high-boiling substances are converted into the gas phase, without too high a heat radiation reaching the substrate to be coated.

This problem is solved with an evaporator device according to the present invention.

The invention, consequently, relates to an evaporator device for coating substrates, in particular for applying an aluminum layer onto OLEDs. To attain high evaporator tube temperatures, such as are necessary for example for the evaporation of materials having low vapor pressure, the heating system has been placed into the interior of the evaporator tube. The thermal losses are thereby minimized and higher tube temperatures are possible at comparably coupled-in heating power.

The advantage attained with the invention comprises in particular that the heating power remains within the evaporator tube and is not radiated outwardly. Hereby only a low power loss occurs, and very high evaporator temperatures can be generated. It is additionally possible to improve the thermal insulation of the evaporator tube against the outside, since the insulation can be directly in contact on the evaporator tube since an outside heater is omitted. Furthermore, a more homogeneous decoupling of the heating energy is attained through the improved symmetry of the structure. In the known evaporators no heating set could be provided in front of the outlet opening for the vapor. This led to some extent to the condensation of evaporation material in the proximity of the outlet opening.

The invention is illustrated in conjunction with the drawings and will be explained in the following in further detail.

### BRIEF DESCRIPTION OF THE FIGURES

FIG. 1 is a cross section through an evaporator device.

FIG. 2 is a perspective view of a portion of the inner wall of an evaporator tube.

FIG. 3 is a perspective view of a portion of the outer wall of the evaporator tube.

FIG. 4 is a perspective view of an evaporator tube with heating elements extending within the evaporator tube.

FIG. 5 is a perspective view of an evaporator tube with a heating device in contact on an evaporator bar.

### DETAILED DESCRIPTION

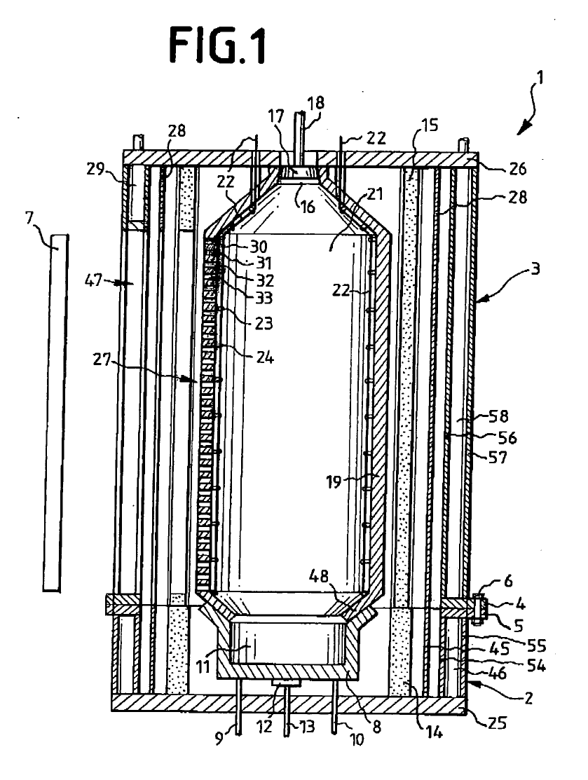

FIG. 1 shows a longitudinal section through an evaporator device 1 comprised of a lower housing part 2 and an upper housing part 3. The upper housing part 3 is herein placed onto the lower housing part 2. The lower and the upper housing part 2, 3 are held together with connection clamps 4, 5 and a connection pin 6. While the lower housing part 2 rests on a base 25, the upper housing part 3 is closed off by a cover 26. Instead of connection clamps 4, 5, a simple plug connection may also be provided.

In the interior of the upper housing part 3 is located an evaporator tube 19 which includes several nozzles 30, 31, 32, 33 disposed linearly one below the other, through which vapor can escape from the evaporator tube. This vapor is deposited on the surface of a substrate 7, which can be moved into the plane of drawing past the evaporator device 1.

Beneath the evaporator tube 19 is provided a crucible 8 on which rests the evaporator tube 19 via a taper 48. The crucible 8 is heated via an electric heating means whose power supply lines are denoted by 9 and 10. The heating means may be, for example, a, not shown, heating coil wound about the crucible 8. The crucible interior 11 is filled with a material to be vaporized. On the underside of crucible 8 is located a heat sensor 12, via which the temperature of the crucible 8 is measured. This heat sensor 12 is connected via an electric terminal 13 with a control system, not shown in FIG. 1, with which the temperature of the crucible 8 can be controlled.

An insulating layer 14 is provided about the crucible 8. About the crucible 8, in turn, at least one shielding tube 45 is placed. The termination to the outside is formed by a cooling tube 46, which is formed by concentric walls 54, 55.

The evaporator tube 19 is also encompassed by a tubular insulating layer 15, which is encompassed by a shielding tube 28. The concentric cylindrical walls 56, 57 following thereon form a cooling space 58 between them.

The evaporator tube 19 terminates at its upper end with an opening 16, which can be closed by means of a plunger 17 and a rod 18.

The cooling spaces 58 and 46 are separately controllable cooling spaces through which may flow a cooling means.

To prevent condensation on the evaporator tube 19 of the vapor rising from the crucible 8, a heating means 22 is provided on the inside of the evaporator tube 19. This heating device is preferably an electric heater 22, which in FIG. 1 is only shown schematically. It may be comprised for example of rod-shaped heating rods, which are retained by electrically insulating spacer blocks 23, 24.

Through this inner heating means 22 very high temperatures can be reached in the interior 21 of the evaporator tube 19, such that even materials with low vapor pressure cannot condense.

The heating rods do not need to be disposed symmetrically in the evaporator tube, such that through the skillful geometric disposition of the heating rods it is possible to heat even those sites at which high thermal losses occur, such as for example at the outlet openings 30 to 33 of the evaporator tube 19.

Instead of on the interior surface of the evaporator tube 19, the heating rods can also be located as a grouping in its center.

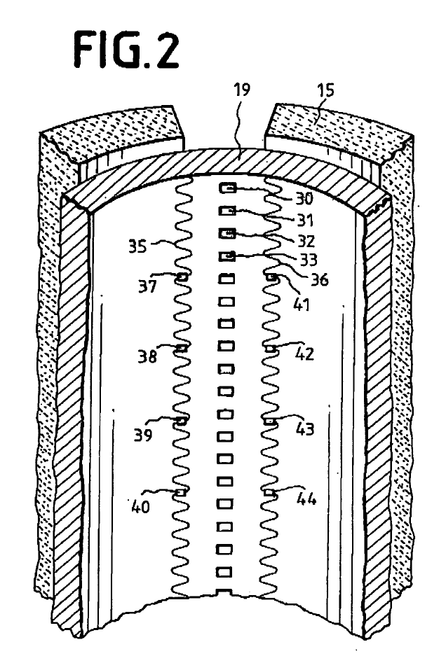

FIG. 2 shows a perspective cut-out of the inside of the evaporator tube 19 with the insulating layer 15. Evident are several nozzles 30 to 33 disposed linearly one above the other, from which the vapor can escape from the inside to the outside. The nozzles 30 to 33 consequently form a linear distributor system, through which the vapor impinges perpendicularly onto the surface of the substrate 7.

On both sides of the nozzles 30 to 33 run two heating elements 35, 36 formed in the shape of meanders, which are connected with the inside wall of the evaporator tube 19 via electrically insulating spacer blocks 37 to 40 and 41 to 44, respectively. The power source supplying the heating elements 35, 36 with electric energy is not shown in FIG. 2.

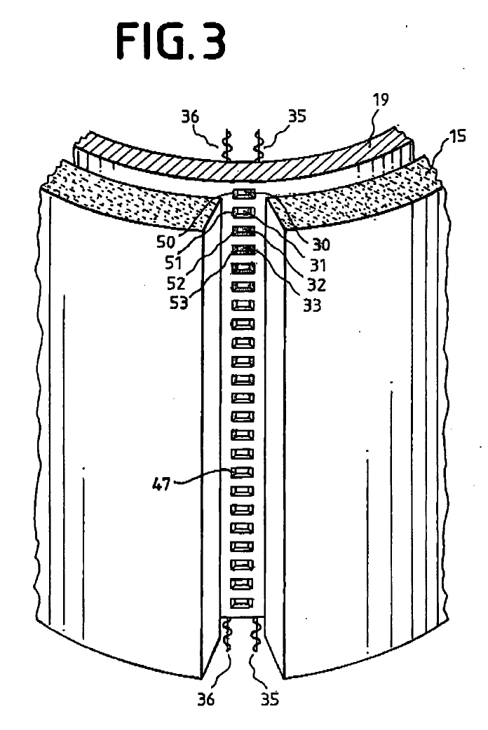

FIG. 3 shows a perspective cut-out of the outside of the evaporator tube 3 with the evaporator tube 19 and the insulating layer 15. The insulating layer 15 encompasses the inner tube 19 nearly completely leaving open a wedge-form window 47. In this window 47 the nozzles 30 to 33 are disposed linearly one above the other, these nozzles 30 to 33 increasing in size toward the outside in the manner of inverse embrasures. The enlargements are denoted by 50 to 53.

For the better shielding of the inner tube 19 and of the insulating layer 15 still further shielding tubes (cf. 28 in FIG. 1) may be provided. In this case, these must have windows which adjoin the window of the insulating layer 15. Such shielding tubes have thermal conductivities of different magnitudes, the thermal conductivity preferably increasing from the inside to the outside.

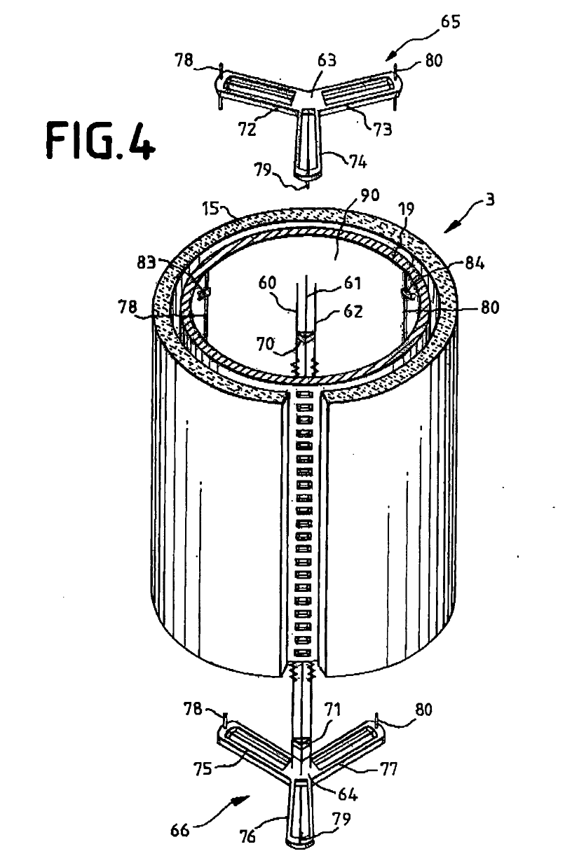

FIG. 4 shows a perspective view of the evaporator tube 19 with the insulating layer 15, with heating elements 60 to 62 being carried through the center of the evaporator tube 3. These heating elements 60 to 62 extend through the centers 63, 64 of two parallel Y-shaped carriers 65, 66, each with three webs 72 to 74 and 75 to 77, respectively. The carrier 66 is disposed in the lower region of the evaporator tube above the crucible, while the upper carrier 65 is disposed closely beneath the upper end of the evaporator tube 19.

To avoid possible contact between the heating elements 60 to 62, they are separated by electrically insulating spacers 70, 71 in the form of a triangle disposed in the vertical direction and at a certain spacing one from the other.

In addition to the inner heating rods 60 to 62, outer heating rods 78 to 80 can also be provided, which are carried through the ends of webs 72 to 74 and 75 to 77, respectively. The heating rods 78 to 80 in this case extend further via spacer blocks 83, 84 along the inner wall 90 of evaporator tube 19. It is understood that the heating rods 78 to 80 can also be provided without the heating elements 60 to 62.

Carriers can also be installed which have even more webs, which also permits accommodating more heating elements. At one end of the web several heating elements can also protrude and run along the tube wall whereby the heating power can still be further increased.

It is understood that the carriers and the heating elements must be comprised of materials having high thermal resistance.

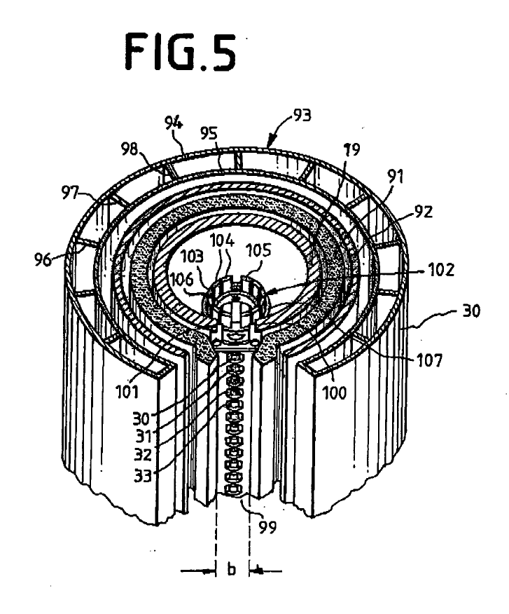

FIG. 5 shows a further disposition of an inner heating system for an evaporator tube 90. The evaporator tube 90 is here encompassed by an insulating layer 91, which, in turn, is encompassed by a metal shielding sheet 92. A cooling tube 93 encompasses the shielding sheet 92, with this cooling tube 93 having two concentric walls 94, 95 between which extend separating webs 96 to 98. Together with the walls 94, 95, these separating webs 96 to 98 form channels through which a cooling fluid can flow. A nozzle bar 99 with nozzles 30 to 32 is flanged onto the ends 100, 101 of the evaporator tube 90. Directly behind the nozzle bar 99 is located an inner heater 102 comprised of several heating rods 103 to 105 disposed in a circle. These heating rods 103 to 105 are braced by inner and outer holding rings 106, 107. Since the nozzle bar 99 projects outwardly, a very small radiation area of width b is formed in connection with the special inner heater 102.

1-11. (canceled)

12. An evaporator device for coating substrates comprising:
an evaporator with a linear distributor; and
a heating system, wherein the surface of the material to be vaporized extends in a first plane, wherein the linear distributor is located in a second plane perpendicular to the first plane and the heating system is provided in the interior of the evaporator.

13. An evaporator device as claimed in claim 12, wherein the heating system is an electric resistance heating system.

14. An evaporator device as claimed in claim 12, wherein the heating system is located in the center of the evaporator.

15. An evaporator device as claimed in claim 12, wherein the heating system is located on the inner wall of the evaporator.

16. An evaporator device as claimed in claim 12, wherein the heating system is disposed directly at the linear distributor opening.

17. An evaporator device as claimed in claim 12, wherein the linear distributor opening is formed by a nozzle bar and that directly opposite the evaporator bar a heating system is provided.

18. An evaporator device as claimed in claim 12, wherein the heating system comprises several heating rods.

19. An evaporator device as claimed in claim 12, wherein the evaporator is tubular.

20. An evaporator device as claimed in claim 12, wherein the heating systems comprises meander-shaped heating elements.

21. An evaporator device as claimed in claim 12, wherein the heating system comprises rod-shaped heating elements.

22. An evaporator device as claimed in claim 18, wherein the heating rods form a cylinder.

23. A method comprising coating a substrate with the evaporator device of claim 12.
